(19) United States
(12) Patent Application Publication
(10) Pub. No.: US 2015/0179823 A1
(43) Pub. Date: Jun. 25, 2015

(54) ELECTRODE STRUCTURE FOR NITRIDE SEMICONDUCTOR DEVICE, PRODUCTION METHOD THEREFOR, AND NITRIDE SEMICONDUCTOR FIELD-EFFECT TRANSISTOR

(71) Applicant: SHARP KABUSHIKI KAISHA, Osaka-shi, Osaka (JP)

(72) Inventor: Daisuke Kurita, Osaka-shi (JP)

(73) Assignee: SHARP KABUSHIKI KAISHA, Osaka-shi, Osaka (JP)

(21) Appl. No.: 14/406,553

(22) PCT Filed: Jun. 26, 2013
(86) PCT No.: PCT/JP2013/067483

§ 371 Date: Dec. 9, 2014

(30) Foreign Application Priority Data
Jun. 29, 2012 (JP) 2012-147116
Jun. 18, 2013 (JP) 2013-127605

(51) Int. Cl. H01L 29/808; H01L 29/201; H01L 29/40; H01L 21/324; H01L 21/311; H01L 21/3205; H01L 21/3213; H01L 29/20; H01L 29/417

(52) U.S. Cl. CPC H01L 29/808; H01L 29/2003; H01L 29/201; H01L 29/401; H01L 29/41725; H01L 21/311; H01L 21/32051; H01L 21/32133; H01L 21/324

(57) ABSTRACT

According to an electrode structure of an embodiment of the invention, an ohmic electrode is provided from recess to a surface of an insulating film without being in contact with the surface of the nitride semiconductor multilayer body, so that the insulating film covers the surface of the AlGaN barrier layer. Accordingly, during the formation process of the ohmic electrode by dry etching, the surface of the nitride semiconductor multilayer body can be protected by the insulating film.

### TECHNICAL FIELD

The present invention relates to an electrode structure for nitride semiconductor device, as well as its production method, in which an ohmic electrode is provided at a recess formed in a nitride semiconductor multilayer body having a heterointerface, and also relates to a nitride semiconductor field-effect transistor including the electrode structure for nitride semiconductor device.

### BACKGROUND ART

There is an electrode structure for nitride semiconductor device of PTL1 (JP 4333652 A), in which a recess is provided in a nitride semiconductor multilayer body and an ohmic electrode is provided at the recess so as to achieve a reduction of the contact resistance.

Also, a nitride semiconductor field-effect transistor including such an electrode structure as described above is shown in PTL2 (JP 2011-249439 A). In the nitride semiconductor field-effect transistor, as shown in FIG. 9, a nitride semiconductor multilayer body 502 is provided on a Si substrate 501, and a source electrode 505, a drain electrode 506 and a gate electrode 507 are provided on the nitride semiconductor multilayer body 502.

The nitride semiconductor multilayer body 502 is so constructed that an AlN buffer layer 521, an undoped GaN layer 523 and an undoped AlGaN layer 524 are formed sequentially on the Si substrate 501. In the nitride semiconductor multilayer body 502, recesses are provided so as to extend from the surface through a heterointerface between the undoped GaN layer 523 and the undoped AlGaN layer 524, and the source electrode 505 and the drain electrode 506 are provided at these recesses. Also, in the undoped AlGaN layer 524, a recess is formed between the source electrode 505 and the drain electrode 506 so as not to reach the heterointerface, and the gate electrode 507 is provided at the recess.

The source electrode 505 and the drain electrode 506 have flanges 505A and 506A extending so as to be in contact with an upper surface of the undoped AlGaN layer 524. On a region extending from the flange 505A of the source electrode 505 to the flange 506A of the drain electrode 506, a first insulating film 511 made from aluminum nitride is provided so as to cover the upper surface the undoped AlGaN layer electrode 507. Further, a second insulating film 512 made from silicon nitride is provided on the first insulating film 511. The second insulating film 512 has a through hole provided therein so as to allow the first insulating film 511 to be exposed between the gate electrode 507 and the drain electrode 506. A field plate 515 is provided so as to fill the through hole of the second insulating film 512 and extend on the second insulating film 512 to reach the source electrode 505.

Unfortunately, the field-effect transistor described above has such problems as shown below.

(1) Since the ohmic metal for making the source electrode 505 and the drain electrode 506 is formed by lift-off process, there arise such problems as elongated lift-off time in diameter-increasing or mass-producing processes.

(2) When the ohmic metal is formed by dry etching in order to solve the problem (1), there arises a problem of occurrence of etching damage to the surface of the undoped AlGaN layer 524.

That is, the coupling cut off by the etching damage comes to an electric-charge trap level, leading to an increase in the on-resistance as a problem. Further, the film thickness of the undoped AlGaN layer decreases in the etching process, so that the concentration of two-dimensional electron gas decrease to cause an increase in the on-resistance. Moreover, the leakage current also increases due to conduction through the level formed by the dry etching, as a further problem.

### CITATION LIST

### Patent Literature

PTL1: JP 4333652 A

PTL2: JP 2011-249439 A

### SUMMARY OF INVENTION

### Technical Problem

Accordingly, an embodiment of the present invention is directed to provide an electrode structure for nitride semiconductor device, as well as a production method therefor and a nitride semiconductor field-effect transistor, capable of reducing the on-resistance and the leakage current.

### Solution to Problem

An electrode structure for nitride semiconductor device of an embodiment of the present invention comprises:

a nitride semiconductor multilayer body having a heterointerface and a recess recessed from a surface thereof toward the heterointerface;

an insulating film provided on the surface of the nitride semiconductor multilayer body and outside the recess; and

an ohmic electrode provided from the recess of the nitride semiconductor multilayer body to a surface of the insulating film and provided so as not to contact the surface of the nitride semiconductor multilayer body.

According to the electrode structure for nitride semiconductor device of the embodiment of the invention, the insulating film covers the surface of the nitride semiconductor multilayer body, and the ohmic electrode is provided from the recess to the surface of the insulating film so as not to be in contact with the surface of the nitride semiconductor multilayer body. Accordingly, during the formation process of the ohmic metal to serve as the ohmic electrode by dry etching, the surface of the nitride semiconductor multilayer body can be protected by the insulating film. Thus, according to an embodiment of the invention, it is possible to form the ohmic metal by dry etching, which allows mass production and larger diameters to be realized, without causing etching damage to the surface of the nitride semiconductor multilayer body. As a result, there can be realized an electrode structure for nitride semiconductor device capable of reducing the on-resistance and the leakage current.

In an electrode structure for nitride semiconductor device according to an embodiment, the nitride semiconductor multilayer body may include:

a first GaN-based semiconductor layer; and

a second GaN-based semiconductor layer stacked on the first GaN-based semiconductor layer to form the heterointerface with the first GaN-based semiconductor layer.

According to the embodiment, since the nitride semiconductor multilayer body is composed of a first GaN-based semiconductor layer and a second GaN-based semiconductor layer, there can be provided an electrode structure for nitride semiconductor device suitable for high-frequency, high-power device.

In an electrode structure for nitride semiconductor device according to an embodiment, the insulating film may include a silicon nitride film or compose a silicon nitride film, a silicon oxynitride film, a silicon carbonitride film or an aluminum nitride film.

According to the embodiment, use of the insulating film allows a reduction of the current collapse to be achieved. The term, current collapse, refers to a phenomenon that on-resistance of a transistor in high-voltage operation becomes higher relative to on-resistance of the transistor in low-voltage operation.

In a nitride semiconductor field-effect transistor according to an embodiment, the nitride semiconductor field-effect transistor may comprise:

the electrode structure for nitride semiconductor device;

a source electrode formed from the ohmic electrode;

a drain electrode formed from the ohmic electrode; and

a gate electrode provided on the nitride semiconductor multilayer body.

According to the embodiment, there can be provided a nitride semiconductor field-effect transistor capable of reducing the on-resistance and the leakage current.

A production method for an electrode structure for nitride semiconductor device of an embodiment of the present invention comprises:

forming an insulating film on a nitride semiconductor multilayer body having a heterointerface;

removing a predetermined region of the insulating film by etching so as to expose a surface of the nitride semiconductor multilayer body;

etching the nitride semiconductor multilayer body with the insulating film used as a mask so as to form recess recessed toward the heterointerface in the nitride semiconductor multilayer body;

heat-treating the insulating film;

forming a metal film on the heat-treated insulating film and in the recess; and

etching and heat-treating the metal film so as to form an ohmic electrode which is provided from the recess to a surface of the insulating film and is not in contact with the surface of the nitride semiconductor multilayer body.

According to the production method for an electrode structure of the embodiment of the invention, during the etching of the metal film, the surface of the nitride semiconductor multilayer body is covered with the insulating film, so that the ohmic electrode is formed from the recess to the surface of the insulating film so as not to be in contact with the surface of the nitride semiconductor multilayer body. Accordingly, during the formation process of the ohmic metal to serve as the ohmic electrode by etching, the surface of the nitride semiconductor multilayer body can be protected by the insulating film. Thus, according to an embodiment of the invention, it is possible to form the ohmic metal by dry etching, which allows mass production and larger diameters to be realized, without causing etching damage to the surface of the nitride semiconductor multilayer body. As a result, there can be produced an electrode structure for nitride semiconductor device capable of reducing the on-resistance and the leakage current.

In a production method for an electrode structure for nitride semiconductor device according to an embodiment,

a temperature for heat treatment of the metal film may be set lower than a temperature for heat treatment of the insulating film.

According to the embodiment, diffusion of the electrode metal into the insulating film due to the heat treatment of the metal film can be suppressed so that leakage currents flowing via the insulating film can be reduced.

### Advantageous Effects of Invention

According to the electrode structure for nitride semiconductor device of this invention, it is possible to form the ohmic metal by dry etching, which allows mass production and larger diameters to be realized, without causing etching damage to the surface of the nitride semiconductor multilayer body. As a result, there can be realized an electrode structure for nitride semiconductor device capable of reducing the on-resistance and the leakage current.

### BRIEF DESCRIPTION OF DRAWINGS

FIG. 1 is a sectional view of a GaN-based field-effect transistor having an embodiment of the electrode structure for nitride semiconductor device according to a first embodiment of the present invention;

FIG. 2 is a process sectional view for explaining a production process of the GaN-based field-effect transistor;

FIG. 3 is a process sectional view subsequent to FIG. 2;

FIG. 4 is a process sectional view subsequent to FIG. 3;

FIG. 5 is a process sectional view subsequent to FIG. 4;

FIG. 6 is a process sectional view subsequent to FIG. 5;

FIG. 7 is a process sectional view subsequent to FIG. 6;

FIG. 8 is a process sectional view subsequent to FIG. 7; and

FIG. 9 is a sectional view of a field-effect transistor having an electrode structure for nitride semiconductor device according to PTL2.

### DESCRIPTION OF EMBODIMENTS

Hereinbelow, the present invention will be described in detail by way of embodiments thereof illustrated in the accompanying drawings.

### First Embodiment

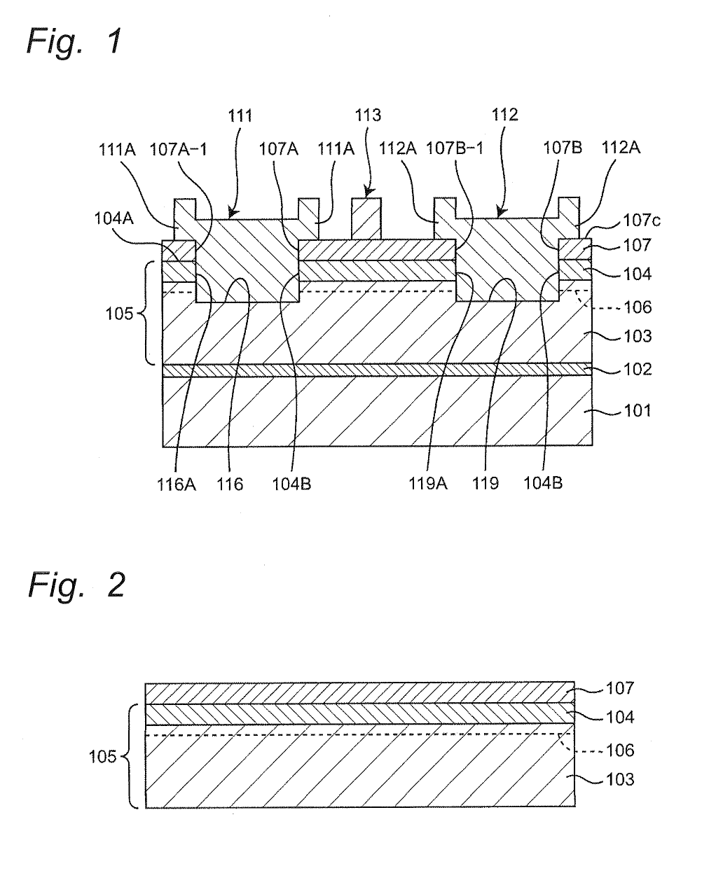

FIG. 1 is a sectional view of a nitride semiconductor device having an embodiment of the electrode structure according to a first embodiment of the invention. The nitride semiconductor device is a GaN-based HFET (Hetero-junction Field Effect Transistor).

As shown in FIG. 1, the nitride semiconductor device has a Si substrate 101, an undoped AlGaN buffer layer 102, an undoped GaN channel layer 103 as an example of a first GaN-based semiconductor layer and an undoped AlGaN barrier layer 104 as an example of a second GaN-based semiconductor layer. The undoped AlGaN buffer layer 102, the undoped GaN channel layer 103 and the undoped AlGaN barrier layer 104 are provided on the Si substrate 101 in this order. A 2DEG (two-dimensional electron gas) layer 106 is generated in vicinity of a heterointerface between the undoped GaN channel layer 103 and the undoped AlGaN barrier layer 104. The undoped GaN channel layer 103 and the undoped AlGaN barrier layer 104 constitute a nitride semiconductor multilayer body 105.

The GaN channel layer 103 may be replaced with an AlGaN layer having such a composition that its band gap is smaller than that of the AlGaN barrier layer 104. Also, for example, an GaN layer having a thickness of about 1 nm may be provided as a cap layer on the AlGaN barrier layer 104.

In the nitride semiconductor multilayer body 105, a recess 116 and a recess 119 are provided at intervals from each other. The recess 116 and the recess 119 extend from a surface 104A of the AlGaN barrier layer 104 so as to reach the GaN channel layer 103 through the AlGaN barrier layer 104 and the 2DEG layer 106. Also, an insulating film 107 is provided on the surface 104A of the AlGaN barrier layer 104. The insulating film 107 is provided outside the recess 116 and the recess 119. That is, the insulating film 107 has an opening 107A connected to the recess 116 and an opening 107B connected to the recess 119. These openings 107A, 107B have side walls 107A-1, 107B-1 which are generally flush with side walls 116A, 119A of the recesses 116, 119, respectively.

A source electrode 111, which is an ohmic electrode, is provided at the recess 116, while a drain electrode 112 is provided at the recess 119. The source electrode 111 fills the recess 116 and extends through the opening 107A of the insulating film 107. The source electrode 111 has a flange 111A extending from the opening 107A of the insulating film 107 to a surface 107C of the insulating film 107. Also, the drain electrode 112 fills the recess 119 and extends through the opening 107B of the insulating film 107. The drain electrode 112 has a flange 112A extending from the opening 107B of the insulating film 107 to the surface 107C of the insulating film 107.

As shown in FIG. 1, the surface 104A of the AlGaN barrier layer 104 is covered with the insulating film 107. Therefore, the source electrode 111 and the drain electrode 112 are in contact with a side wall 104B of the AlGaN barrier layer 104 forming the side walls 116A and 119A of the recesses 116 and 119, but are not in contact with the surface 104A of the AlGaN barrier layer 104.

The source electrode 111 and the drain electrode 112 are composed of a multilayer of Ti/Al/TiN in which Ti, Al and TiN layer are layered in this order, as an example.

Further, a gate electrode 113 is formed between the source electrode 111 and the drain electrode 112 on the insulating film 107. The gate electrode 113 is made from TiN or WN as an example. The gate electrode 113 may be a Schottky electrode that extends through the insulating film 107 so as to reach the AlGaN barrier layer 104.

In the nitride semiconductor device constituted as described above, a channel is formed by the two-dimensional electron gas (2DEG) layer 106 generated in vicinity of the interface between the GaN layer 103 and the AlGaN layer 104, and the channel is controlled by an application of a voltage to the gate electrode 113 to turn on and off the HFET having the source electrode 111, the drain electrode 112 and the gate electrode 113. The HFET is a normally-ON type transistor that when a negative voltage is applied to the gate electrode 113, a depletion layer is formed in the GaN layer 103 under the gate electrode 113 to turn off the HFET and when zero volt is applied to the gate electrode 113, no depletion layer is formed in the GaN layer 103 under the gate electrode 113 to turn on the HFET.

Next, a production method for the nitride semiconductor device will be described with reference to FIGS. 2 to 8. In FIGS. 2 to 8, for an easier seeing of the drawings, the Si substrate and the undoped AlGaN buffer layer is not shown.

First, as shown in FIG. 2, an undoped AlGaN buffer layer (not shown), an undoped GaN channel layer 103 and an undoped AlGaN barrier layer 104 are formed sequentially on a Si substrate (not shown) by using MOCVD (Metal Organic Chemical Vapor Deposition) process. The undoped GaN channel layer 103 has a thickness of 1 μm as an example, and the undoped AlGaN barrier layer 104 has a thickness of 30 nm as an example. These GaN channel layer 103 and AlGaN barrier layer 104 constitute a nitride semiconductor multilayer body 105. In FIG. 2, reference sign 106 denotes a two-dimensional electron gas (2DEG) layer 106 formed in vicinity of the heterointerface between the GaN channel layer 103 and the AlGaN barrier layer 104.

Next, for example, a silicon nitride film 107 having a thickness of 200 nm is deposited on the AlGaN barrier layer 104 by plasma CVD (Chemical Vapor Deposition) process to form an insulating film 107. The growth temperature for the insulating film 107 is set to 225° C. as an example in this case, but may be set within a range of 200° C. to 400° C. Also, the film thickness of the insulating film 107 is set to 200 nm as an example in this case, but may be set within a range of 20 nm to 400 nm.

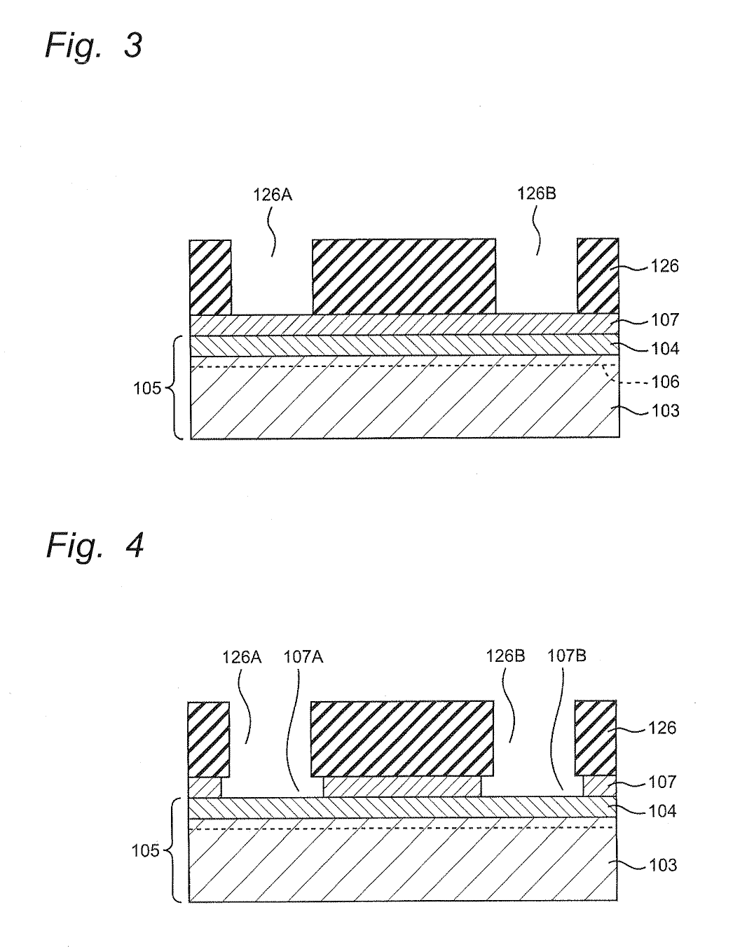

Next, as shown in FIG. 3, a photoresist layer 126 is formed on the insulating film 107 and then openings 126A and 126B are formed in the photoresist layer 126 by exposure to light and development processes. Then, wet etching is performed under the condition that the photoresist layer 126 having the openings 126A and 126B formed therein is used as a mask. As a result, as shown in FIG. 4, openings 107A and 107B are formed in the insulating film 107. The openings 107A and 107B may be formed in the insulating film 107 by dry etching instead of the wet etching.

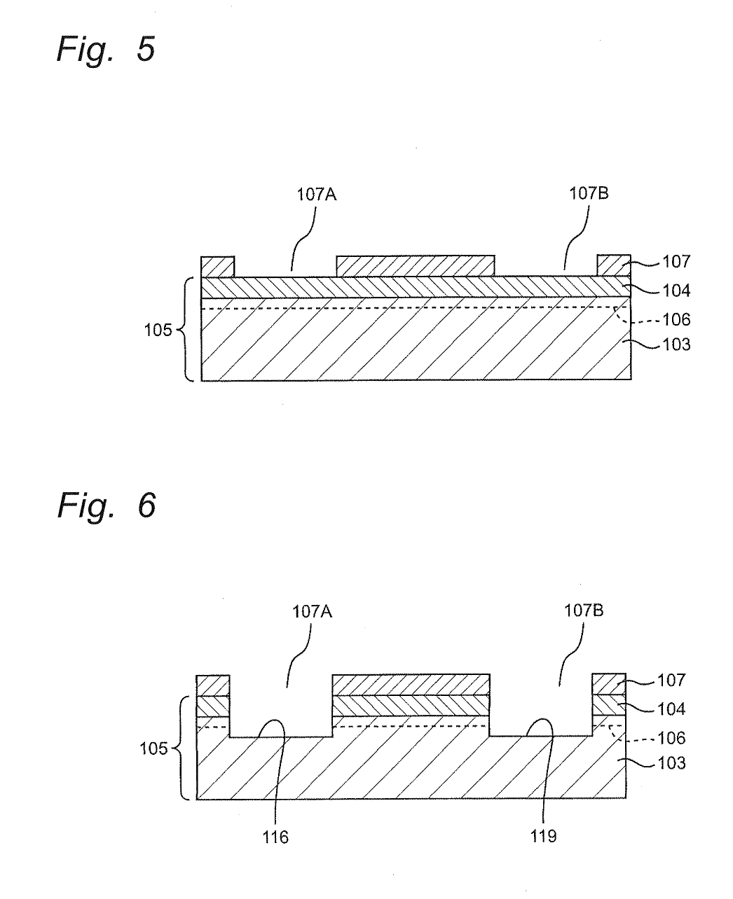

Next, as shown in FIG. 5, the photoresist layer 126 is removed.

Next, as shown in FIG. 6, dry etching or wet etching is performed with the insulating film 107 used as a mask, by which recesses 116 and 119 are formed from the AlGaN barrier layer 104 to the GaN channel layer 103. Subsequently, oxygen plasma processing and acid cleaning are performed. The oxygen plasma processing and acid cleaning may not be performed.

Next, the insulating film 107 is subjected to heat treatment. The heat treatment is executed, in this case, in a nitrogen atmosphere at 500° C. for 5 minutes, as an example. The temperature for the heat treatment may be set within a range of 500° C. to 850° C. as an example.

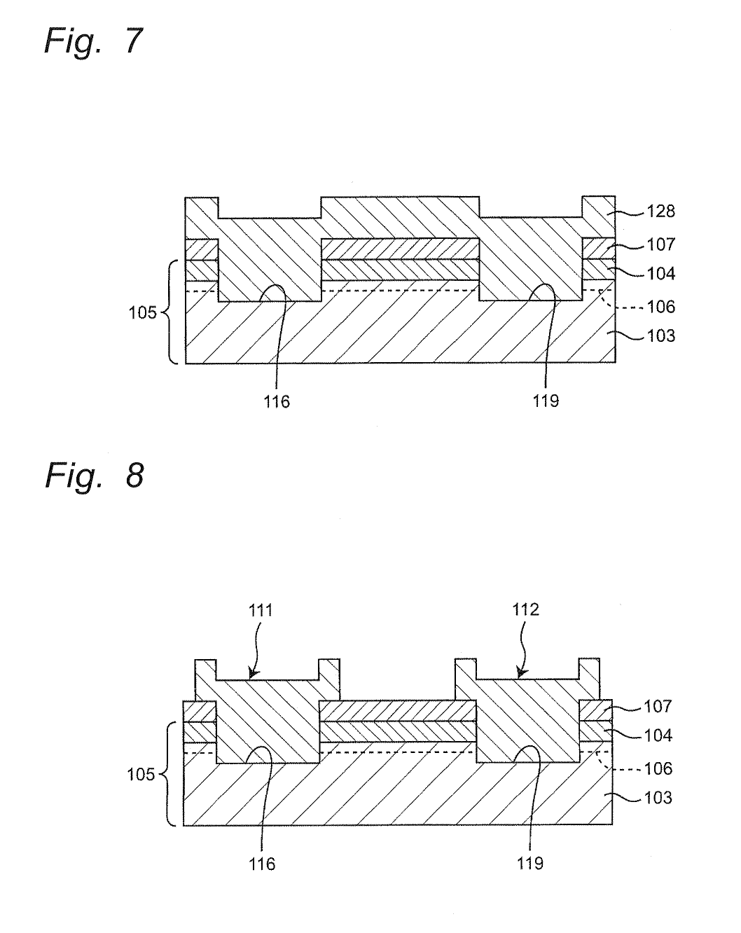

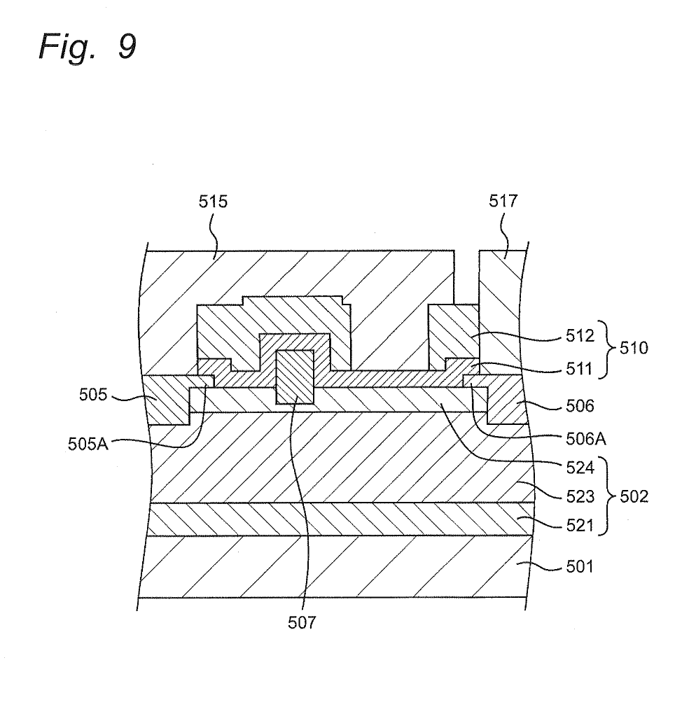

Next, as shown in FIG. 7, Ti, Al and TiN layers are sequentially stacked on the insulating film 107 and in the recesses 106 and 109 by sputtering to make up a multilayer of Ti/Al/TiN, so that a multilayer metal film 128 to serve as the ohmic electrode is formed. In this case, the TiN layer is a cap layer for protecting a multilayer of Ti/Al from subsequent steps.

In the embodiment, for the sputtering, a ratio α/β of a layer thickness α (nm) of the Ti layer to a layer thickness β (nm) of the Al layer is set, for example, to within a range of 2/100 to 40/100 so that an atomic ratio of Ti to Al in the TiAl alloy of the ohmic electrodes formed subsequent to a later-described ohmic annealing process falls within a range of 2.0 to 40 atom % (e.g., 8 atom %).

In addition, instead of the above sputtering, the Ti and Al may be vapor deposited.

Next, as shown in FIG. 8, patterns of ohmic electrodes 111 and 112 are formed by normal photolithography and dry etching.

Then, the substrate with the ohmic electrodes 111 and 112 formed thereon is annealed at temperatures of e.g. 400° C. to 500° C. for 10 minutes or more, by which ohmic contacts can be obtained between the two-dimensional electron gas (2DEG) layer 106 and the ohmic electrodes 111 and 112. In this case, the contact resistance can be reduced significantly, as compared with cases where the substrate is annealed at high temperatures over 500° C. (e.g., 600° C. or higher). Performing the annealing of the substrate at lower temperatures within the range of 400° C. to 500° C. makes it possible to suppress diffusion of the electrode metal into the insulating film 107, so that characteristics of the insulating film 107 are not adversely affected. The annealing of the substrate at lower temperatures makes it possible to prevent deterioration of current collapse and characteristic variations due to denitrification from the GaN layer 103. The annealing time, although set to 10 minutes or more in this case, may appropriately be set to a time duration that allows Ti to be sufficiently diffused into Al. The term ‘current collapse’ refers to a phenomenon that on-resistance of a transistor in high-voltage operation becomes higher relative to on-resistance of the transistor in low-voltage operation.

The ohmic electrodes 111 and 112 become the source electrode 111 and the drain electrode 112, and a gate electrode made from TiN or WN or the like is formed between the source electrode 111 and the drain electrode 112 in subsequent process.

According to the electrode structure of the embodiment, the ohmic electrodes 111 and 112 are provided from the recesses 116 and 119 to the surface 104A of the AlGaN barrier layer 104, i.e., the surface 1070 of the insulating film 107 without being in contact with the surface of the nitride semiconductor multilayer body 105, so that the insulating film 107 covers the surface 104A of the AlGaN barrier layer 104. Accordingly, during the formation process of the ohmic electrodes 111 and 112 by dry etching, the surface of the nitride semiconductor multilayer body 105 can be protected by the insulating film 107. Thus, according to the electrode structure, it is possible to form the ohmic electrodes 111 and 112 by dry etching, which allows mass production and larger diameters to be realized, without causing etching damage to the surface of the nitride semiconductor multilayer body 105, so that the on-resistance and the leakage current can be reduced.

According to the nitride semiconductor device, with a nitride semiconductor device of the recess structure in which the ohmic electrodes 111 and 112 are partly filled in the recesses 116 and 119 formed so as to extend through the AlGaN barrier layer 104 and reach an upper-side portion of the GaN channel layer 103, it is possible to reduce the contact resistance between the ohmic electrodes 111 and 112 and the two-dimensional electron gas (2DEG) layer 106 in vicinity of the heterointerface between the GaN channel layer 103 and the AlGaN barrier layer 104. For example, with the temperature for annealing the ohmic electrodes 111 and 112 set to 500° C., the contact resistance is 0.66 Ωmm. It can be considered that the formation of the recesses 116 and 119 by etching (dry etching or wet etching) with the insulating film 107 used as a mask made it possible to suppress the coverage of etching onto the surface 104A of the AlGaN barrier layer 104 to suppress damage to the surface 104A of the AlGaN barrier layer 104, thus achieving a reduction of the contact resistance.

According to the production method for the nitride semiconductor device, the insulating film 107 is formed on the AlGaN barrier layer 104, the insulating film 107 is heat-treated (e.g., at 500° C. for 5 minutes), the multilayer metal film 128 is formed, the multilayer metal film 128 is heat-treated (ohmic annealing), and the source electrode 111 and the drain electrode 112 is formed. Thus, diffusion of the electrode metal into the insulating film 107 can be suppressed so that leakage currents flowing via the insulating film 107 can be reduced. Further, by setting the temperature for the heat treatment (ohmic annealing) to temperatures lower than the heat treatment temperature (e.g., 400° C.) of the insulating film 107, the diffusion of the electrode metal into the insulating film 107 can be suppressed so that the leakage currents can be reduced.

According to the electrode structure of the embodiment, the insulating film 107 is sandwiched between the flange 112A of the drain electrode 112 equivalent to an ohmic electrode and the AlGaN layer 104. Thus, the ON withstand voltage can be improved as compared with an electrode structure in which the flange of the drain electrode is in direct contact with the surface of the AlGaN layer. The term ON withstand voltage′ refers to a withstand voltage of the source-drain voltage upon switching of a field-effect transistor as a switching device from OFF to ON. It has been found out by the present inventors that for example, in a normally-ON field-effect transistor, a high electric field region is formed in vicinity of a gate electrode-side end of the drain electrode upon switching from an OFF state, in which a voltage of 0 V is applied to the source electrode, a voltage of −10 V is applied to the gate electrode and a high voltage (e.g., 600 V) is applied to the drain electrode, to an ON state by application of a voltage of 0 V to the gate electrode. It is important to improve the turn-ON withstand voltage (ON withstand voltage) as well as the turn-OFF withstand voltage (OFF withstand voltage) as to withstand voltage characteristics of the field-effect transistor as a switching device.

In the above-described nitride semiconductor device, the recesses 116 and 119 provided in the nitride semiconductor multilayer body 105 are provided so as to extend through the AlGaN barrier layer 104 and the 2DEG layer 106. However, the recesses 116 and 119 may be provided so as to extend through the AlGaN barrier layer 104 but not to extend through the 2DEG layer 106. Furthermore, the recesses 116 and 119 may be provided so as not to extend through the AlGaN barrier layer 104.

In the above nitride semiconductor device, the gate electrode 113 is provided on the insulating film 107 to constitute a MOS structure. Alternatively, a gate electrode 113 as a Schottky electrode may be provided in the AlGaN barrier layer 104 exposed at an opening provoded in the insulating film 107.

In the above embodiment, the multilayer of Ti/Al/TiN is formed to make up the ohmic electrodes. However, TiN layer may not be stacked to form a multilayer of Ti/Al. And Au, Ag, Pt or the like may be stacked on the multilayer of Ti/Al.

In the above embodiment, the nitride semiconductor device has the Si substrate. However, the nitride semiconductor device may have not only the Si substrate, but a sapphire substrate or SiC substrate. A nitride semiconductor layers may be grown on a sapphire substrate or SiC substrate. And the nitride semiconductor layer may be grown on a substrate composed of a nitride semiconductor such as growing an AlGaN layer on a GaN substrate. An buffer layer may be provided between a substrate and a nitride semiconductor layer. An AlN hetero-characteristic improving layer having a thickness of about 1 nm may be provided between the AlGaN barrier layer 104 and the GaN channel layer 103 of the nitride semiconductor multilayer body 105.

As materials of the insulating film 107 in the above nitride semiconductor device, for example, SiNx, SiO₂, AlN, Al₂O₃ and the like are used. In particular, the insulating film 107 has preferably a multilayer film structure composed of a SiN film of decayed stoichiometry formed on the surface of the AlGaN barrier layer 104 for current collapse suppression and a protective film formed from SiO₂ or SiN for surface protection on the SiN film. Further, SiON or SiCN may be used as the material of the insulating film 107. The insulating film 107 may be provided by forming an AlN film on a SiN film and by forming a SiON film on the AlN film.

### Second Embodiment

An electrode structure for nitride semiconductor device according to a second embodiment is so constituted that the insulating film 107 of the first embodiment is replaced with an insulating film including a silicon oxynitride (SIGN) film or an insulating film including a silicon carbonitride (SiCN) film. Use of the insulating film including a SiON film or a SiCN film makes it possible to reduce the current collapse.

Instead of the insulating film including a SiON film, an insulating film composed of a SiON film may also be used.

Instead of the insulating film including a SiCN film, an insulating film composed of a SiCN film may also be used.

### Third Embodiment

An electrode structure for nitride semiconductor device according to a third embodiment is so constituted that the insulating film 107 of the first embodiment is replaced with an insulating film including an aluminum oxide (Al₂O₃) film or an insulating film including a silicon oxide (SiO₂) film. Use of the insulating film including an Al₂O₃ film or a SiO₂ film makes it possible to reduce the current collapse.

Instead of the insulating film including an Al₂O₃ film, an insulating film composed of an Al₂O₃ film may also be used.

Instead of the insulating film including a SiO₂ film, an insulating film composed of a SiO₂ film may also be used.

### Fourth Embodiment

An electrode structure for nitride semiconductor device according to a fourth embodiment is so constituted that the insulating film 107 of the first embodiment is replaced with an insulating film including an AlN film. Use of the insulating film including an AlN film makes it possible to reduce the current collapse.

Instead of the insulating film including an AlN film, an insulating film composed of an AlN film may also be used.

The invention may be applied not only to the above nitride semiconductor of an HFET of the normally-ON type, but to nitride semiconductor device of the normally-OFF type. Further, the invention may be applied not only to a field-effect transistor having a Schottky electrode, but to a field-effect transistor having the insulated-gate structure.

The nitride semiconductor for nitride semiconductor device of the invention may be a nitride semiconductor expressed by AlₓIn_{y}Ga_{1-x-y}N (x≧0, y≧0, 0≦x+y≦1).

Although specific embodiments of the present invention have been described hereinabove, yet the invention is not limited to the above embodiments and may be carried out as they are changed and modified in various ways within the scope of the invention.

### REFERENCE SIGNS LIST

101 Si substrate
102 undoped AlGaN buffer layer
103 undoped GaN channel layer
104 undoped AlGaN barrier layer
104A surface
104B side wall
105 nitride semiconductor multilayer body
106 2DEG layer
107 insulating film
107A, 107B opening
107A-1, 107B-1 side wall
111 source electrode
112 drain electrode
113 gate electrode
116, 119 recess
116A, 119A side wall
126 photoresist layer
128 multilayer metal film

1-5. (canceled)

6. An electrode structure for nitride semiconductor device comprising:
a nitride semiconductor multilayer body having a heterointerface and a recess recessed from a surface thereof toward the heterointerface;
an insulating film provided on the surface of the nitride semiconductor multilayer body and outside the recess; and
an ohmic electrode provided from the recess of the nitride semiconductor multilayer body to a surface of the insulating film and provided so as not to contact the surface of the nitride semiconductor multilayer body.

7. The electrode structure for nitride semiconductor device as claimed in claim 6, wherein
the nitride semiconductor multilayer body includes:
a first GaN-based semiconductor layer; and
a second GaN-based semiconductor layer stacked on the first GaN-based semiconductor layer to form the heterointerface with the first GaN-based semiconductor layer.

8. A nitride semiconductor field-effect transistor comprising:
the electrode structure for nitride semiconductor device as claimed in claim 6;
a source electrode formed from the ohmic electrode;
a drain electrode formed from the ohmic electrode; and
a gate electrode provided on the nitride semiconductor multilayer body.

9. A production method for an electrode structure for nitride semiconductor device, comprising:
forming an insulating film on a nitride semiconductor multilayer body having a heterointerface;
removing a predetermined region of the insulating film by etching so as to expose a surface of the nitride semiconductor multilayer body;
etching the nitride semiconductor multilayer body with the insulating film used as a mask so as to form a recess recessed toward the heterointerface in the nitride semiconductor multilayer body;
heat-treating the insulating film;
forming a metal film on the heat-treated insulating film and in the recess; and
etching and heat-treating the metal film so as to form an ohmic electrode which is provided from the recess to a surface of the insulating film and is not in contact with the surface of the nitride semiconductor multilayer body.

10. The production method for an electrode structure for nitride semiconductor device as claimed in claim 9, wherein
a temperature for heat treatment of the metal film is set lower than a temperature for heat treatment of the insulating film.
